(19) United States
(12) Patent Application Publication
(10) Pub. No.: US 2026/0173372 A1
(43) Pub. Date: Jun. 18, 2026

(54) CHANNEL BACKSIDE LINERS FOR THRESHOLD VOLTAGE TUNING

(71) Applicant: Micron Technology, Inc., Boise, ID (US)

(72) Inventors: Valay Dineshbhai Shah, Kuna, ID (US); Andrew Bicksler, Nampa, ID (US); Dmitry Mikulik, Meridian, ID (US); Marc Aoulaiche, Boise, ID (US); Srinath Venkatesan, Boise, ID (US)

(21) Appl. No.: 18/982,784

(22) Filed: Dec. 16, 2024

(51) Int. Cl. H10B 43/27; H01L 21/768; H10B 43/35

(52) U.S. Cl. CPC H10B 43/27; H10W 20/076; H10W 20/089; H10B 43/35

(57) ABSTRACT

A variety of applications can include a memory device having a pillar and a pillar fill with memory cells arranged in tiers along the pillar fill. A channel structure for the memory cells can be arranged along the pillar fill. A liner structure can be structured along the pillar fill and disposed between and contacting the channel structure and the pillar fill. The liner structure can be a vertical arrangement of multiple liners. The multiple liners can be arranged with appropriate thicknesses and material to provide a tuning of the threshold voltages of the memory cells. Additional devices, systems, and methods are discussed.

### FIELD OF THE DISCLOSURE

Embodiments of the disclosure relate generally to memory devices, and more specifically, to designs of components of the memory devices.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive

random-access memory (RRAM), magnetoresistive random-access memory (MRAM), or three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line. Properties of such memory devices can be improved by enhancements to the design or fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIGS. 1-5 illustrate different examples of decks of pillars of memory devices having multi-liner liner structures as backside liners to channel structures, according to various embodiments.

FIG. 6 is a flow diagram of features of an example method of forming a memory device with a multi-liner liner structure as a backside liner to a channel structure, according to various embodiments.

FIG. 7 illustrates a block diagram of an example machine having one or more memory devices structured with a multi-liner liner structure implemented as a backside liner to a channel structure to tune the threshold voltages of memory cells associated with the channel structure, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Both NOR and NAND flash architecture semiconductor memory arrays of flash memory devices are accessed through decoders that activate specific memory cells by selecting an access line (WL) coupled to gates of specific memory cells. In a NOR architecture semiconductor memory array, once activated, the selected memory cells place their data values on data lines, causing different currents to flow depending on the state at which a particular cell is programmed. In a NAND architecture semiconductor memory array, a relatively high bias voltage is applied to a drain-side select gate (SGD) line. Access lines coupled to the gates of the unselected memory cells of each group are driven at a specified pass voltage to operate the unselected memory cells of each group as pass transistors (e.g., to pass current in a manner unrestricted by their stored data values). Current then flows in the line between the source line and the data line through each series-coupled group, restricted only by the selected memory cells of each group, placing current-encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC has been referred to as a memory cell that can store two bits of data per cell (e.g., one of four programmed states). MLC is used herein in its broader context, to refer to any memory cell(s) that can store more than one bit of data per cell (i.e., that can represent more than two programmed states). Herein, a memory cell that can store two bits of data per cell (e.g., one of four programmed states) is referred to as a dual-level cell (DLC). A triple-level cell (TLC) refers to a memory cell that can store three bits of data per cell (e.g., one of eight programmed states). A quad-level cell (QLC) can store four bits of data per cell, and a penta-level cell (PLC) can store five bits of data per cell.

In NAND technology, such as replacement gate (RG)-NAND technology, the threshold voltage (VT) of a memory cell of a newly fabricated NAND memory device tends to become more negative with tier pitch scaling. Tier pitch scaling is a reduction in vertical distance between neighboring tiers of memory cells. This negative trend poses a challenge to measure the corresponding VTs and may include the use of special circuits or boards with associated low negative biases. Herein, threshold voltage (VT) of a memory cell of a newly fabricated NAND memory device is referred to as cell UV-Vt and a memory cell can also be referred to as a cell.

High-k liners, such as but not limited to aluminum oxide (AlO_{X}) or hafnium oxide (HfO_{X}) liners, can be used to increase (make more positive) the cell UV-Vt. A high-k liner is a liner having a composition of a high-k dielectric, where a high dielectric is a dielectric having a dielectric constant greater than the dielectric constant of silicon dioxide (SiO₂). Using a AlOₓ liner at the channel backside has shown to increase the cell UV-Vt by approximately 2 V. A channel backside is the region contacting a channel structure, where the region is on a side of the channel structure opposite the side on which the storage structure of a memory cell interfaces with the channel structure. The storage structure of a memory cell can interface with the channel structure through a tunnel dielectric. The source of the cell UV-Vt increase is the fixed charge in the high-k film, which can be toggled from skewing the high-k film thickness. However, for high aspect ratio nodes, high-k film uniformity is critical and, hence, scaling below 10 Å is challenging. So, in practical terms, an increase of approximately 2 V is significantly high and unusable. A high aspect ratio node corresponds to pillars having more than 276 tiers of cells.

In a vertical memory device, a pillar of tiers of cells can be constructed as a number of groups of tiers, where a group of tiers of cells can be constructed as a deck of cells. Deck to deck cell UV-Vt offset can pose difficulty in process tuning and trim optimizations in the fabrication procedures.

In various embodiments, a high-k liner can be used in combination with one or more liners to tune the Vt according to specifications of the application of the memory device. For example, a high-k film liner can be sandwiched between an oxide and a nitride or a carbon liner to target the cell UV-Vt to a desired value without compromising the uniformity of high-k liner. Oxide liners, nitride liners and carbon liners can decrease (make more negative) the cell UV-Vt by a range from 0.5 V to 1.5 V. Combination of a high-k liner and oxide or nitride liners can be used to target the cell UV-Vt to a desired value. The high-k liner can be a high-k dielectric liner having a dielectric constant equal to or greater than a dielectric constant of aluminum oxide. The high-k liner can be a high-k oxide liner. The high-k oxide can be, but is not limited to, AlOₓ, HfOₓ, zirconium oxide (ZrOₓ), other high-k dielectric having a dielectric constant greater than or equal to the dielectric constant of AlOₓ, or combination of high-k dielectrics within the liner providing a dielectric constant greater than or equal to the dielectric constant of AlOₓ. A high-k dielectric can be realized by other ternary oxides that have negative fixed charge. An oxide liner can have a material composition of an oxide having a dielectric constant less than or equal to the dielectric constant of SiO₂. The oxide liner can be, but is not limited to, a SiO₂ or silicon oxycarbide (SiO_{X}C_{Y}). A nitride liner can have, but is not limited to, a material composition including nitrogen without having oxygen. The nitride liner can be, but is not limited to, a silicon nitride (SiN_{X}) liner. The thickness of the SiN_{X} can be adjusted based on the fixed charge it may possess. A carbon liner can have, but is not limited to, a material composition including carbon without having oxygen. The carbon liner can be, but is not limited to, a silicon carbide (SiC_{X}) liner.

Using a sandwich layer of oxide liner: high-k liner: nitride liner can also help produce less interface defect generation when formed directly on a channel structure. For example, changing the backside channel liner from a single AlOX deposition on the channel structure to a sandwich layer of oxide liner: AlO_{X} liner: nitride liner on the channel structure can generate less interface defects when the multi-liner liner structure is formed directly on the channel structure. Additionally, deck-to-deck cell UV-Vt offsets can be lowered by depositing a multi-liner liner structure having a high-k liner and making the multi-liner liner structures non-uniform across multiple decks. Quality and properties of multi-liner liner structures of oxide liner, nitride liner, or carbon liners can dictate cell UV-Vt compensation from use of a high-dielectric liner in the multi-liner liner structure and overall cell performance.

Consider depositing AlOX liner post forming a channel structure. This AlO_{X} liner formation can increase cell UV-Vt. Further, a AlOX liner thickness of 10 Å can match the cell UV-Vt of a AlO_{X} liner thickness of 20 Å. This matching can pose a challenge to target the cell UV-Vt to a desired value using liner thickness. Cell UV-Vt can be decreased by depositing an oxide liner, a nitride liner, or a carbon liner post channel structure formation. This property can be used together with a AlO_{X} liner to target the cell UV-Vt to a desired value. The AlO_{X} liner can be replaced by a liner of another high-k dielectric of equal or greater dielectric constant. Nitride liner thickness and its quality can govern the positive charge that the multi-liner film possesses.

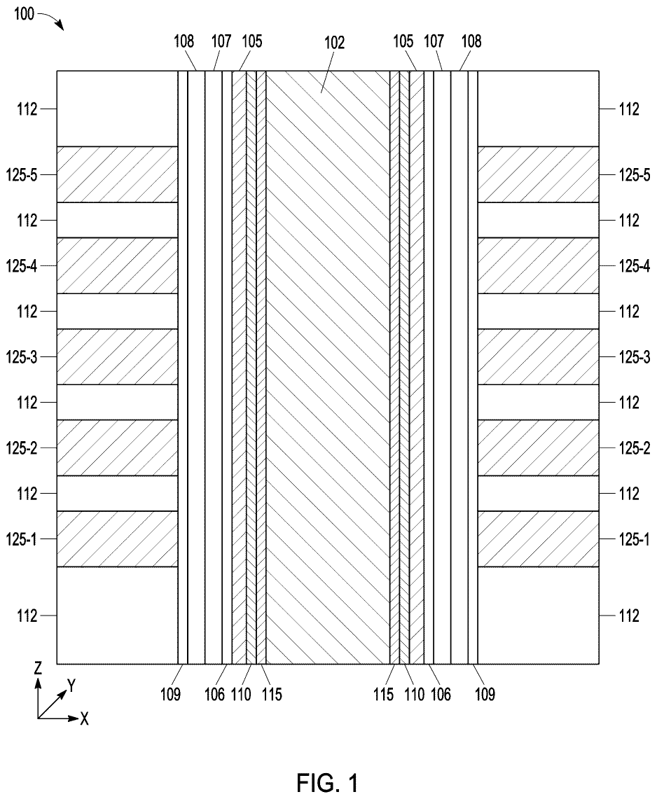

FIG. 1 illustrates an embodiment of an example of a deck 100 of a pillar of a memory device having a multi-liner liner structure as a backside liner to a channel structure 105 of the memory cells of deck 100. Though deck 100 is shown with five tiers, deck 100 can have more or fewer than five tiers. In the example of FIG. 1, the memory cells of each tier can have components that are structured in a continuous manner along deck 100, but associated with different gates. A first tier of deck 100 can include a tunnel region 106 contacting channel structure 105 with a charge trap region 107 on and contacting tunnel region 106. A dielectric blocking region 108 can be structured on and contacting charge trap region 107 and a dielectric barrier 109 can be structured on and contacting dielectric blocking region 108. Dielectric barrier 109 separates dielectric blocking region 108 from a gate 125-1 for a memory cell of the first tier. A thin dielectric layer relative to dielectric blocking region 108 constructed as dielectric barrier 109 between dielectric blocking region 108 and gate 125-1 enables an enhanced tunneling barrier that prevents the back-tunneling of electrons from gate 125-1 through dielectric blocking region 108 into charge trap region 107. Such a structure can limit operational erase saturation to small positive or small negative VT levels. Alternatively, the combination of dielectric blocking region 108 and dielectric barrier 109 can be implemented as a single region or multiple regions in excess of two regions in deck 100.

A memory cell of the second tier of deck 100 can include tunnel region 106 on and contacting channel structure 105, charge trap region 107, dielectric blocking region 108, and a dielectric barrier 109, as structured for the memory cell of the first tier of deck 100. The memory cell of the second tier can include a gate 125-2 on and contacting dielectric barrier 109. A memory cell of the third tier of deck 100 can include tunnel region 106 on and contacting channel structure 105, charge trap region 107, dielectric blocking region 108, and a dielectric barrier 109, as structured for the memory cell of the first tier of deck 100. The memory cell of the third tier can include a gate 125-3 on and contacting dielectric barrier 109. A memory cell of the fourth tier of deck 100 can include tunnel region 106 on and contacting channel structure 105, charge trap region 107, dielectric blocking region 108, and a dielectric barrier 109, as structured for the memory cell of the first tier of deck 100. The memory cell of the fourth tier can include a gate 125-4 on and contacting dielectric barrier 109. A memory cell of the fifth tier of deck 100 can include tunnel region 106 on and contacting channel structure 105, charge trap region 107, dielectric blocking region 108, and a dielectric barrier 109, as structured for the memory cell of the first tier of deck 100. The memory cell of the fifth tier can include a gate 125-5 on and contacting dielectric barrier 109. Insulation material 112 separates the memory cells of the different tiers from each other.

A first liner 110 can be structured vertically on and contacting channel structure 105. First liner 110 can be a high-k liner. The high-k dielectric of first liner 110 can be, but is not limited to, AlO_{X}, HfO_{X}, ZrO_{X}, other high-k dielectric having a dielectric constant greater than or equal to the dielectric constant of AlO_{X}, or combination of high-k dielectrics within first liner 110 providing a dielectric constant greater than or equal to the dielectric constant of AlOX. Other ternary oxides that have negative fixed charge may be used, where the thickness used for the same Vt tuning can be different. A second liner 115 can be structured vertically on and contacting first liner 110. Second liner 115 can be a nitride liner, a carbon liner, an oxide liner, or a liner of two or more of nitride, carbon, or oxide. The combination of first liner 110 and second liner 115 can form a multi-liner liner structure that runs along channel structure 105 for at least the length of the five tiers. The multi-liner liner structure is sandwiched between channel structure 105 and a pillar fill 102, contacting both channel structure 105 and pillar fill 102. Pillar fill 102 can be realized by a chemical vapor deposition (CVD) oxide. The CVD oxide can be CVD silicon oxide (SiO_{X}). Other electrically insulating material can be used for pillar fill 402. With first liner 110 being a high-k liner, second liner 115 can be structured on and contacting the high-k dielectric liner such that the high-k dielectric liner is sandwiched between channel structure 105 and second liner 115. The thicknesses of the component liners of the multi-liner liner structure in combination with the selections of the materials of the component liners can be selected to target cell UV-Vt to a desired value without compromising the uniformity of the high-k liner.

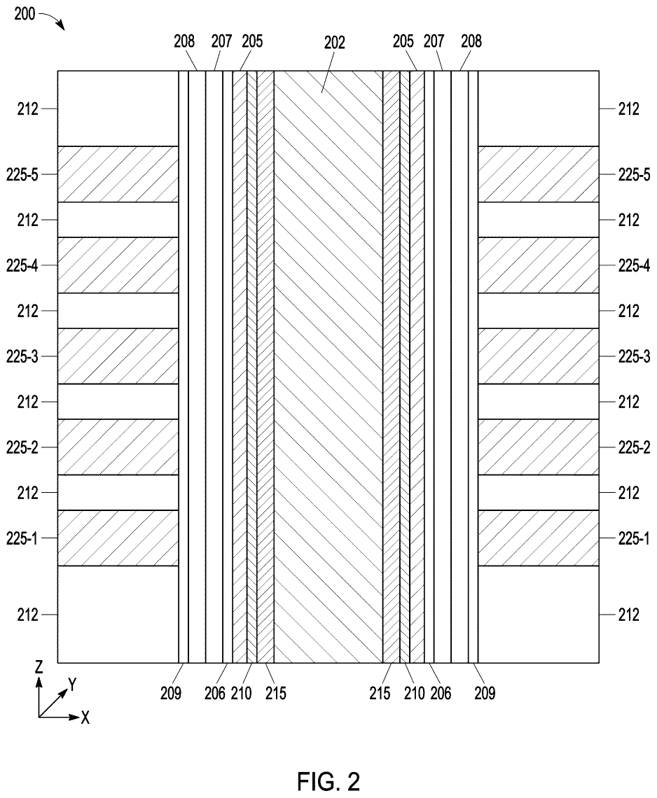

FIG. 2 illustrates an embodiment of an example of a deck 200 of a pillar of a memory device having a multi-liner liner structure as a backside liner to a channel structure 205 of the memory cells of deck 200. Though deck 200 is shown with five tiers, deck 200 can have more or fewer than five tiers. In the example of FIG. 2, the memory cells of each tier can have components that are structured in a continuous manner along deck 200, but associated with different gates. A first tier of deck 200 can include a tunnel region 206 contacting channel structure 205 with a charge trap region 207 on and contacting tunnel region 206. A dielectric blocking region 208 can be structured on and contacting charge trap region 207 and a dielectric barrier 209 can be structured on and contacting dielectric blocking region 208. Dielectric barrier 209 separates dielectric blocking region 208 from a gate 225-1 for a memory cell of the first tier. Alternatively, the combination of dielectric blocking region 208 and dielectric barrier 209 can be implemented as a single region or multiple regions in excess of two regions in deck 200.

A memory cell of the second tier of deck 200 can include tunnel region 206 on and contacting channel structure 205, charge trap region 207, dielectric blocking region 208, and a dielectric barrier 209, as structured for the memory cell of the first tier of deck 200. The memory cell of the second tier can include a gate 225-2 on and contacting dielectric barrier 209. A memory cell of the third tier of deck 200 can include tunnel region 206 on and contacting channel structure 205, charge trap region 207, dielectric blocking region 208, and a dielectric barrier 209, as structured for the memory cell of the first tier of deck 200. The memory cell of the third tier can include a gate 225-3 on and contacting dielectric barrier 209. A memory cell of the fourth tier of deck 200 can include tunnel region 206 on and contacting channel structure 205, charge trap region 207, dielectric blocking region 208, and a dielectric barrier 209, as structured for the memory cell of the first tier of deck 200. The memory cell of the fourth tier can include a gate 225-4 on and contacting dielectric barrier 209. A memory cell of the fifth tier of deck 200 can include tunnel region 206 on and contacting channel structure 205, charge trap region 207, dielectric blocking region 208, and a dielectric barrier 209, as structured for the memory cell of the first tier of deck 200. The memory cell of the fifth tier can include a gate 225-5 on and contacting dielectric barrier 209. Insulation material 212 separates the memory cells of the different tiers from each other.

A first liner 210 can be structured vertically on and contacting channel structure 205. First liner 210 can be a high-k liner. The high-k dielectric of first liner 210 can be, but is not limited to, AlO_{X}, HfO_{X}, ZrO_{X}, other high-k dielectric having a dielectric constant greater than or equal to the dielectric constant of AlOX, or combination of high-k dielectrics within the first liner providing a dielectric constant greater than or equal to the dielectric constant of AlOX. A second liner 215 can be structured vertically on and contacting first liner 210. Second liner 215 can be a nitride liner, a carbon liner, an oxide liner, or a liner of two or more of nitride, carbon, or oxide. The combination of first liner 210 and second liner 215 can form a multi-liner liner structure that runs along channel structure 205 for at least the length of the five tiers. The multi-liner liner structure is sandwiched between channel structure 205 and a pillar fill 202, contacting both channel structure 205 and pillar fill 202. Pillar fill 202 can be realized by a CVD oxide. The CVD oxide can be CVD SiO_{X}. Other electrically insulating material can be used for pillar fill 402. With first liner 210 being a high-k liner, second liner 215 can be structured on and contacting the high-k dielectric liner such that the high-k dielectric liner is sandwiched between channel structure 205 and second liner 215. The multi-liners of the liner structure for deck 200 can be constructed in a similar manner as the multi-liners of the liner structure for deck 100 of FIG. 1, except that the outer liner, which is second liner 215, contacting pillar fill 202 is significantly thicker than the outer liner of the liner structure for deck 100 of FIG. 1, which is second liner 115, that contacts pillar fill 102. The thickness of second liner 215 of deck 200 can be at least twice as large as the thickness of second liner 115 of deck 100. The thicknesses of the component liners of the multi-liner liner structure in combination with the selections of the materials of the component liners can be selected to target cell UV-Vt to a desired value without compromising the uniformity of the high-k liner.

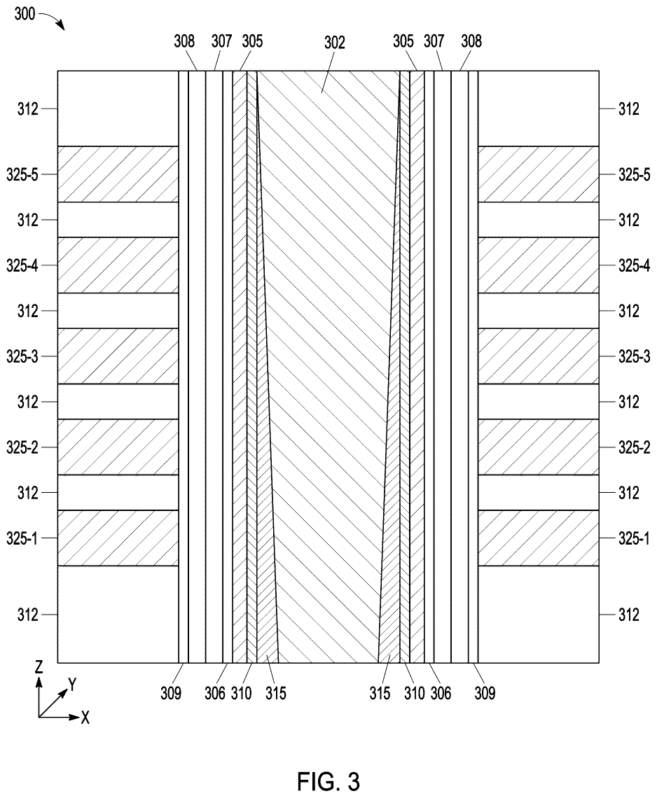

FIG. 3 illustrates an embodiment of an example of a deck 300 of a pillar of a memory device having a multi-liner liner structure as a backside liner to a channel structure 305 of the memory cells of deck 300. Though deck 300 is shown with five tiers, deck 300 can have more or fewer than five tiers. In the example of FIG. 3, the memory cells of each tier can have components that are structured in a continuous manner along deck 300, but associated with different gates. A first tier of deck 300 can include a tunnel region 306 contacting channel structure 305 with a charge trap region 307 on and contacting tunnel region 306. A dielectric blocking region 308 can be structured on and contacting charge trap region 307 and a dielectric barrier 309 can be structured on and contacting dielectric blocking region 308. Dielectric barrier 309 separates dielectric blocking region 308 from a gate 325-1 for a memory cell of the first tier. Alternatively, the combination of dielectric blocking region 308 and dielectric barrier 309 can be implemented as a single region or multiple regions in excess of two regions in deck 300.

A memory cell of the second tier of deck 300 can include tunnel region 306 on and contacting channel structure 305, charge trap region 307, dielectric blocking region 308, and a dielectric barrier 309, as structured for the memory cell of the first tier of deck 300. The memory cell of the second tier can include a gate 325-2 on and contacting dielectric barrier 309. A memory cell of the third tier of deck 300 can include tunnel region 306 on and contacting channel structure 305, charge trap region 307, dielectric blocking region 308, and a dielectric barrier 309, as structured for the memory cell of the first tier of deck 300. The memory cell of the third tier can include a gate 325-3 on and contacting dielectric barrier 309. A memory cell of the fourth tier of deck 300 can include tunnel region 306 on and contacting channel structure 305, charge trap region 307, dielectric blocking region 308, and a dielectric barrier 309, as structured for the memory cell of the first tier of deck 300. The memory cell of the fourth tier can include a gate 325-4 on and contacting dielectric barrier 309. A memory cell of the fifth tier of deck 300 can include tunnel region 306 on and contacting channel structure 305, charge trap region 307, dielectric blocking region 308, and a dielectric barrier 309, as structured for the memory cell of the first tier of deck 300. The memory cell of the fifth tier can include a gate 325-5 on and contacting dielectric barrier 309. Insulation material 312 separates the memory cells of the different tiers from each other.

A first liner 310 can be structured vertically on and contacting channel structure 305. First liner 310 can be a high-k liner. The high-k dielectric of first liner 310 can be, but is not limited to, AlO_{X}, HfO_{X}, ZrO_{X}, other high-k dielectric having a dielectric constant greater than or equal to the dielectric constant of AlO_{X}, or combination of high-k dielectrics within the first liner providing a dielectric constant greater than or equal to the dielectric constant of AlO_{X}. A second liner 315 can be structured vertically on and contacting first liner 310 and structured to taper in thickness from a top region of deck 300 to a bottom region of deck 300. The taper of second liner 315 can be realized as a linear variation of the thickness of second liner 315. Second liner 315 can have a non-uniform thickness as it runs along first liner 310. The thickness of second liner 315 can vary along first liner 310 according to a tuning function for cell UV-Vt along deck 300. Second liner 315 can be a nitride liner, a carbon liner, an oxide liner, or a liner of two or more of nitride, carbon, or oxide. The combination of first liner 310 and second liner 315 can form a multi-liner liner structure that runs along channel structure 305 for at least the length of the five tiers. The multi-liner liner structure is sandwiched between channel structure 305 and a pillar fill 302, contacting both channel structure 305 and pillar fill 302. Pillar fill 302 can be realized by a CVD oxide. The CVD oxide can be CVD SiO_{X}. Other electrically insulating material can be used for pillar fill 302. With first liner 310 being a high-k liner, second liner 315 can be structured on and contacting the high-k dielectric liner such that the high-k dielectric liner is sandwiched between channel structure 305 and second liner 315 with respect to the gates of the memory cells of the five tiers. The thicknesses of the component liners of the multi-liner liner structure in combination with the selections of the materials of the component liners can be selected to target cell UV-Vts to a desired value without compromising the uniformity of the high-k liner.

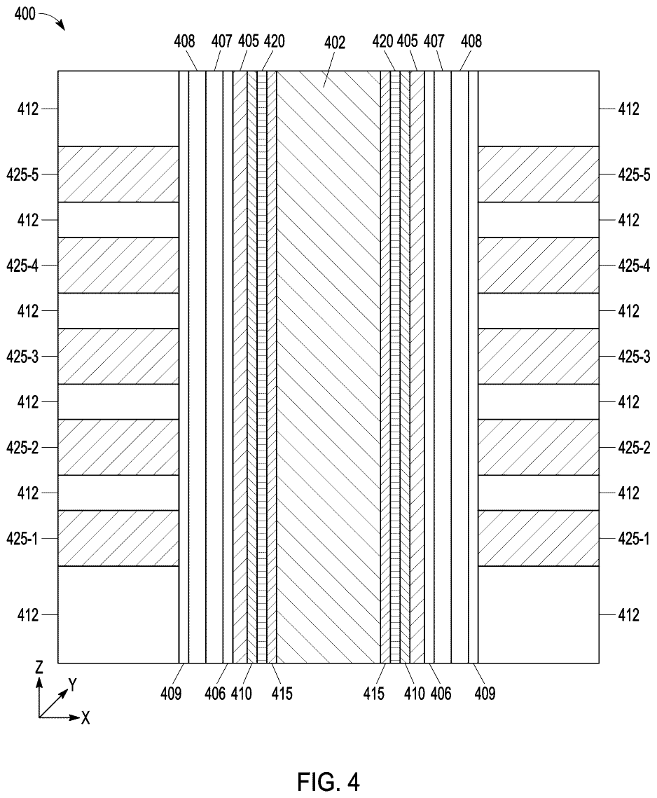

FIG. 4 illustrates an embodiment of an example of a deck 400 of a pillar of a memory device having a multi-liner liner structure as a backside liner to a channel structure 405 of the memory cells of deck 400. Though deck 400 is shown with five tiers, deck 400 can have more or fewer than five tiers. In the example of FIG. 4, the memory cells of each tier can have components that are structured in a continuous manner along deck 400, but associated with different gates. A first tier of deck 400 can include a tunnel region 406 contacting channel structure 405 with a charge trap region 407 on and contacting tunnel region 406. A dielectric blocking region 408 can be structured on and contacting charge trap region 407 and a dielectric barrier 409 can be structured on and contacting dielectric blocking region 408. Dielectric barrier 409 separates dielectric blocking region 408 from a gate 425-1 for a memory cell of the first tier. Alternatively, the combination of dielectric blocking region 408 and dielectric barrier 409 can be implemented as a single region or multiple regions in excess of two regions in deck 400.

A memory cell of the second tier of deck 400 can include tunnel region 406 on and contacting channel structure 405, charge trap region 407, dielectric blocking region 408, and a dielectric barrier 409, as structured for the memory cell of the first tier of deck 400. The memory cell of the second tier can include a gate 425-2 on and contacting dielectric barrier 409. A memory cell of the third tier of deck 400 can include tunnel region 406 on and contacting channel structure 405, charge trap region 407, dielectric blocking region 408, and a dielectric barrier 409, as structured for the memory cell of the first tier of deck 400. The memory cell of the third tier can include a gate 425-3 on and contacting dielectric barrier 409. A memory cell of the fourth tier of deck 400 can include tunnel region 406 on and contacting channel structure 405, charge trap region 407, dielectric blocking region 408, and a dielectric barrier 409, as structured for the memory cell of the first tier of deck 400. The memory cell of the fourth tier can include a gate 425-4 on and contacting dielectric barrier 409. A memory cell of the fifth tier of deck 400 can include tunnel region 406 on and contacting channel structure 405, charge trap region 407, dielectric blocking region 408, and a dielectric barrier 409, as structured for the memory cell of the first tier of deck 400. The memory cell of the fifth tier can include a gate 425-5 on and contacting dielectric barrier 409. Insulation material 412 separates the memory cells of the different tiers from each other.

A first liner 410 can be structured vertically on and contacting channel structure 405. First liner 410 can be an oxide liner. The oxide liner can be, but is not limited to, a SiO_{X} liner or, alternatively, a dielectric liner of non-high-k dielectric material. A second liner 420 can be structured vertically on and contacting first liner 410. Second liner 420 can be a high-k liner. The high-k dielectric of second liner 420 can be, but is not limited to, AlO_{X}, HfO_{X}, ZrO_{X}. other high-k dielectric having a dielectric constant greater than or equal to the dielectric constant of AlO_{X}, or combination of high-k dielectrics within second liner 420 providing a dielectric constant greater than or equal to the dielectric constant of AlO_{X}. First liner 410 can be implemented to provide a better interface between channel structure 405 and the high-k film of second liner 420. A third liner 415 can be structured vertically on and contacting second liner 420. Third liner 415 can be a nitride liner, a carbon liner, an oxide liner, or a liner of two or more of nitride, carbon, or oxide. In a variation, third liner 415 can be structured on and contacting second liner 420 in a tapered manner similar to the arrangement of second liner 315 on and contacting first liner 310 of deck 300 of FIG. 3. The combination of first liner 410, second liner 420, and third liner 415 can form a multi-liner liner structure that runs along channel structure 405 for at least the length of the five tiers. The multi-liner liner structure is sandwiched between channel structure 405 and a pillar fill 402, contacting both channel structure 405 and pillar fill 402. Pillar fill 402 can be realized by a CVD oxide. The CVD oxide can be CVD SiO_{X}. Other electrically insulating material can be used for pillar fill 402. With second liner 420 being a high-k liner, second liner 420 can be structured on and contacting first liner 410, such that the high-k dielectric liner is sandwiched between a non-high-k dielectric liner and a liner of a nitride, a carbon, an oxide, or two or more of nitride, carbon, or oxide. The thicknesses of the component liners of the multi-liner liner structure in combination with the selections of the materials of the component liners can be selected to target cell UV-Vt to a desired value without compromising the uniformity of the high-k liner.

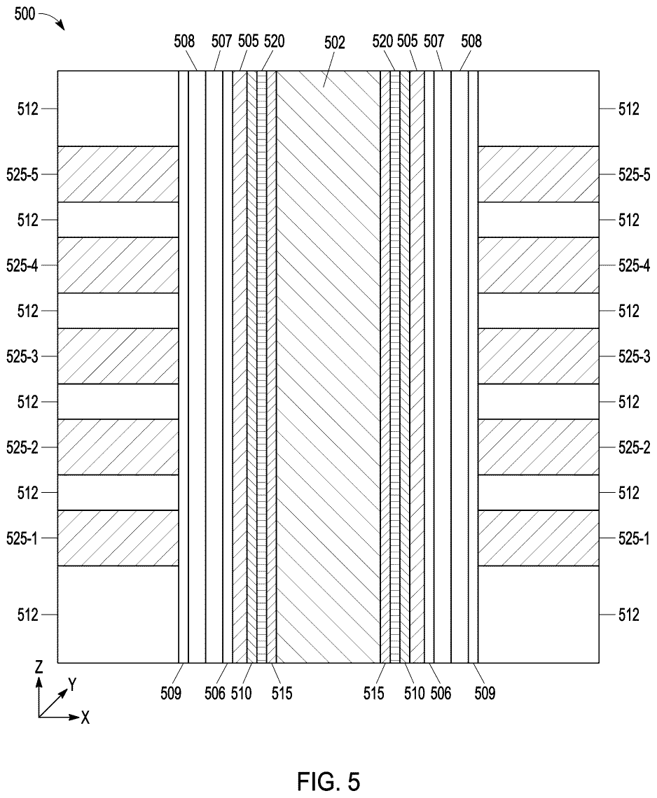

FIG. 5 illustrates an embodiment of an example of a deck 500 of a pillar of a memory device having a multi-liner liner structure as a backside liner to a channel structure 505 of the memory cells of deck 500. Though deck 500 is shown with five tiers, deck 500 can have more or fewer than five tiers. In the example of FIG. 5, the memory cells of each tier can have components that are structured in a continuous manner along deck 500, but associated with different gates. A first tier of deck 500 can include a tunnel region 506 contacting channel structure 505 with a charge trap region 507 on and contacting tunnel region 506. A dielectric blocking region 508 can be structured on and contacting charge trap region 507 and a dielectric barrier 509 can be structured on and contacting dielectric blocking region 508. Dielectric barrier 509 separates dielectric blocking region 508 from a gate 525-1 for a memory cell of the first tier. Alternatively, the combination of dielectric blocking region 508 and dielectric barrier 509 can be implemented as a single region or multiple regions in excess of two regions in deck 500.

A memory cell of the second tier of deck 500 can include tunnel region 506 on and contacting channel structure 505, charge trap region 507, dielectric blocking region 508, and a dielectric barrier 509, as structured for the memory cell of the first tier of deck 500. The memory cell of the second tier can include a gate 525-2 on and contacting dielectric barrier 509. A memory cell of the third tier of deck 500 can include tunnel region 506 on and contacting channel structure 505, charge trap region 507, dielectric blocking region 508, and a dielectric barrier 509, as structured for the memory cell of the first tier of deck 500. The memory cell of the third tier can include a gate 525-3 on and contacting dielectric barrier 509. A memory cell of the fourth tier of deck 500 can include tunnel region 506 on and contacting channel structure 505, charge trap region 507, dielectric blocking region 508, and a dielectric barrier 509, as structured for the memory cell of the first tier of deck 500. The memory cell of the fourth tier can include a gate 525-4 on and contacting dielectric barrier 509. A memory cell of the fifth tier of deck 500 can include tunnel region 506 on and contacting channel structure 505, charge trap region 507, dielectric blocking region 508, and a dielectric barrier 509, as structured for the memory cell of the first tier of deck 500. The memory cell of the fifth tier can include a gate 525-5 on and contacting dielectric barrier 509. Insulation material 512 separates the memory cells of the different tiers from each other.

A first liner 510 can be structured vertically on and contacting channel structure 505. First liner 510 can be an oxide liner. The oxide liner can be, but is not limited to, a SiO_{X} liner or, alternatively, a dielectric liner of non-high-k dielectric material. A second liner 520 can be structured vertically on and contacting first liner 510. Second liner 520 can be a nitride liner or a carbon liner. A third liner 515 can be structured vertically on and contacting second liner 520. Third liner 515 can be a high-k liner. The high-k dielectric of third liner 520 can be, but is not limited to, AlO_{X}, HfO_{X}, ZrO_{X}, other high-k dielectric having a dielectric constant greater than or equal to the dielectric constant of AlO_{X}, or combination of high-k dielectrics within third liner 520 providing a dielectric constant greater than or equal to the dielectric constant of AlO_{X}. First liner 510 can be implemented to provide a better interface between channel structure 505 and the nitride or carbon of second liner 520. In a variation, third liner 515 can be structured on and contacting second liner 520 in a tapered manner similar to the arrangement of second liner 315 on and contacting first liner 310 of deck 300 of FIG. 3. The combination of first liner 510, second liner 520, and third liner 515 can form a multi-liner liner structure that runs along channel structure 505 for at least the length of the five tiers. The multi-liner liner structure is sandwiched between channel structure 505 and a pillar fill 502, contacting both channel structure 505 and pillar fill 502. Pillar fill 502 can be realized by a CVD oxide. The CVD oxide can be CVD SiO_{X}. Other electrically insulating material can be used for pillar fill 502. The thicknesses of the component liners of the multi-liner liner structure in combination with the selections of the materials of the component liners can be selected to target cell UV-Vt to a desired value without compromising the uniformity of the high-k liner.

Various oxide liners, nitride liners, and carbon liners implemented as channel backside liners can decrease the cell UV-Vt. Various high-k liners implemented as channel backside liners can increase the cell UV-Vt. By combining different liners with appropriate thicknesses as a liner structure having multiple liners, the multi-liner liner structure can be implemented as a channel backside liner to tune cell UV-Vts. The use of a liner structure having multiple liners has been demonstrated in FIGS. 1-5. Other variations of a multiple-liner liner structure can be implemented to meet specifications of cell UV-Vts in memory devices. Such a memory device can include a pillar having a pillar fill with memory cells arranged in tiers along the pillar fill, a channel structure for the memory cells arranged along the pillar fill, and a liner structure along the pillar fill and disposed between and contacting the channel structure and the pillar fill. The liner structure can be a vertical arrangement of multiple liners, with a liner of the multiple liners on and contacting the pillar fill having a material composition different from material composition of the pillar fill.

The multi-liner liner structures of FIGS. 1-5 can be formed after formation of channel structure X05, tunnel region X06, charge trap region X07, dielectric blocking region X08 and dielectric barrier X09, for X=1, 2, 3, 4, 5, for the memory cells of the tiers of the corresponding decks. Formation of these regions can be initiated from a formation of alternate layers of insulation layers and sacrificial layers. An opening can be formed in which a pillar of memory cells can be formed. After forming the opening, dielectric barrier X09 can be formed on a wall of the opening, followed by formation of dielectric blocking region X08, charge trap region X07, tunnel region X06, and channel structure X05 in sequence. The multi-liner liner structure can be formed after forming channel structure X05 followed by a pillar fill X02. The set of gates in each of the structures of FIGS. 1-5, gates X25-J, J=1, 2, 3, 4, 5 can be formed in a replacement process of the sacrificial layers.

The multi-liner liner structures of FIGS. 1-5 can be formed with other structural designs of tiers of memory tiers. One or more of tunnel region X06, charge trap region X07, dielectric blocking region X08 and dielectric barrier X09, for X=1, 2, 3, 4, 5, can be formed as individual regions and not as a continuous region along the decks of the pillar of memory cells. In the various alternative embodiments, the regions between individual one or more of tunnel region X06, charge trap region X07, dielectric blocking region X08 or dielectric barrier X09 can be a dielectric including but not limited to a void. A void in a structure is a region of the structure without solid material and without liquid material. A void may be in the form of an evacuated region, an air gap, a gas-filled region, or similar construction. An air gap in a structure or between structures is a gap or region that is filled with air. Herein, the term air gap may include ambient gases enclosed in the gap, such as during formation of the gap. In each of these alternative designs, the channel structures, X05 for X=1, 2, 3, 4, 5, can be continuous regions along the associated pillars.

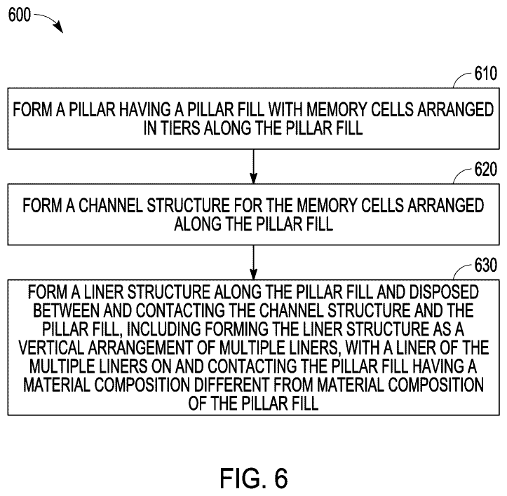

FIG. 6 is a flow diagram of features of an embodiment of an example method 600 of forming a memory device having a multi-liner liner structure as a backside liner to a channel structure to tune the threshold voltages of memory cells associated with the channel structure. At 610, a pillar is formed having a pillar fill with memory cells arranged in tiers along the pillar fill. At 620, a channel structure is formed for the memory cells arranged along the pillar fill. The channel structure can be formed as part of forming the memory cells before forming the pillar fill. At 630, a liner structure is formed along the pillar fill and disposed between and contacting the channel structure and the pillar fill. The liner structure can be formed on and contacting the channel structure with the pillar fill formed on and contacting the liner structure. The liner structure is formed as a vertical arrangement of multiple liners, with a liner of the multiple liners on and contacting the pillar fill having a material composition different from material composition of the pillar fill.

Variations of method 600 or methods similar to method 600 can include a number of different embodiments that may be combined depending on the application of such methods or the architecture or process flow of an integrated circuit for which such methods are implemented. Such methods can include forming the liner structure by forming a high-k dielectric liner on and contacting the channel structure for the memory cells in a deck of the memory cells; and forming a second liner on and contacting the high-k dielectric liner such that the high-k dielectric is sandwiched between the channel structure and the second liner. The high-k dielectric liner can include, but is not limited to, dielectric materials that have a dielectric constant greater than or equal to the dielectric constant of AlO_{X}. The second liner can be a nitride liner, a carbon liner, an oxide liner, or a liner of two or more of nitride, carbon, or oxide.

Variations of method 600 or methods similar to method 600 can include forming a second liner having a thickness based on a target threshold voltage of the memory cells. Variations can include forming the second liner having a thickness at least twice a thickness of a high-k dielectric liner in the liner structure. Variations can include omitting the second liner if use of the high-k dielectric liner attains the target VT. Variations can include forming the second liner having a varying thickness along a vertical direction of the pillar. The thickness can vary linearly along the vertical direction.

Variations of method 600 or methods similar to method 600 can include forming the liner structure by forming a high-k liner sandwiched between an oxide liner and another liner, where the materials of the oxide liner and the other liner are different from material of the pillar fill. Variations of method 600 or methods similar to method 600 can include forming the liner structure with a third liner sandwiched between an oxide liner and a high-k liner.

Variations of method 600 or methods similar to method 600 can include forming the channel structure on a side of an opening in a stack for the tiers of memory cells. After forming the channel structure, forming the liner structure on the channel structure vertically adjacent the tiers of memory cells, where the multiple liners of the liner structure are formed as two or more vertical liners adjacent each other. After forming the liner structure, the pillar fill can be formed such that the liner structure is sandwiched between the channel structure and the pillar fill and contacts the channel structure and the pillar fill. In method 600, methods similar to method 600, and variations of method 600, high-k dielectric of a high-k liner can be, but is not limited to, AlO_{X}, HfO_{X}, ZrO_{X}. other high-k dielectric having a dielectric constant greater than or equal to the dielectric constant of AlO_{X}, or combination of high-k dielectrics within the liner providing a dielectric constant greater than or equal to the dielectric constant of AlO_{X}. Additionally, such methods can include, but are not limited to, forming SiO₂ or SiO_{X}C_{Y} as an oxide liner, forming SiN as a nitride liner, or forming SiC as a carbon liner.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and Internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, an SSD, an MMC, or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

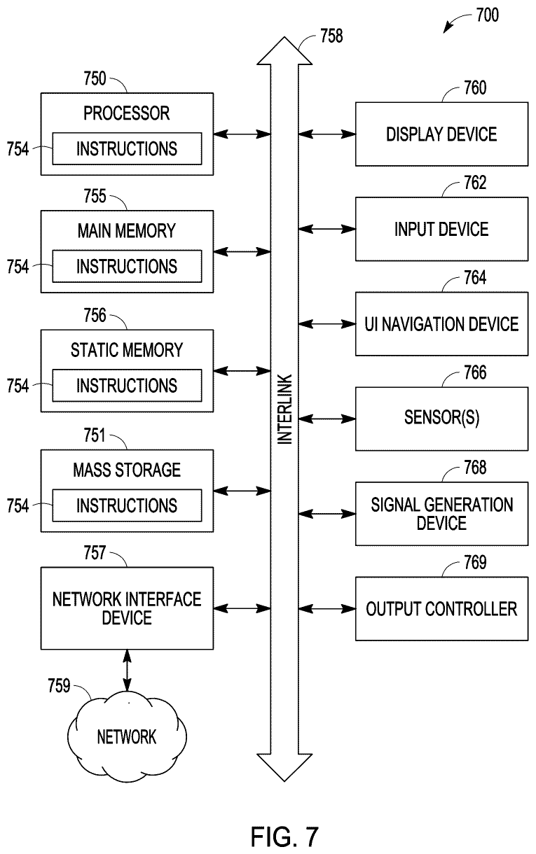

FIG. 7 illustrates a block diagram of an example machine 700 having one or more memory devices structured with a dielectric liner implemented as a backside liner contacting a channel structure to tiers of memory cells, where the dielectric liner is sandwiched between the channel structure and pillar fill of the pillar along which the tiers of memory cells are structured. The backside liner was implemented to tune the cell UV-Vts for the memory cells. The backside liners can be implemented in a manner similar to a backside liner as demonstrated in FIGS. 1-5 or similar structures. The machine 700, having one or more such memory devices, may operate as a standalone machine or may be connected, for example networked, to other machines.

In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more methodologies, such as cloud computing, software as a service (SaaS), other computer cluster configurations. The example machine 700 can be arranged to operate with one or more memory devices having multi-liner liner structures implemented as backside liners for channel structures to tune cell UV-Vts, as taught herein.

The machine (e.g., computer system) 700 may include a hardware processor 750 (e.g., a CPU, a GPU, a hardware processor core, or any combination thereof), a main memory 754, and a static memory 756, some or all of which may communicate with each other via an interlink (e.g., bus) 758. The machine 700 may further include a display device 760, an alphanumeric input device 762 (e.g., a keyboard), and a user interface (UI) navigation device 764 (e.g., a mouse). In an example, the display device 760, input device 762, and UI navigation device 764 may be a touch screen display. The machine 700 may additionally include a mass storage device (e.g., drive unit) 751, a signal generation device 768 (e.g., a speaker), a network interface device 753, and one or more sensors 766, such as a global positioning system (GPS) sensor, compass, accelerometer, or other sensor. The machine 700 may include an output controller 769, such as a serial (e.g., USB, parallel, or other wired or wireless (e.g., infrared (IR), near field communication (NFC), etc.) connection to communicate or control one or more peripheral devices (e.g., a printer, card reader, etc.).

The machine 700 may include machine-readable media on which is stored one or more sets of data structures or instructions 755 (e.g., software) embodying or utilized by the machine 700 to perform any one or more of the techniques or functions for which the machine 700 is designed. The machine-readable media can include main memory 754, static memory 756, or mass storage device 751. The instructions 755 may reside, completely or at least partially, within main memory 754, within static memory 756, within the mass storage device 751, or within the hardware processor 750 during execution thereof by the machine 700.

While each of the machine-readable media is illustrated as a single medium, the term “machine-readable medium” may include a single medium or multiple media (e.g., a centralized or distributed database, or associated caches and servers) configured to store the one or more instructions 755. The term “machine-readable medium” may include any medium that is capable of storing, encoding, or holding instructions for execution by the machine 700 and that cause the machine 700 to perform any one or more of the techniques to which the machine 700 is designed, or that is capable of storing, encoding, or holding data structures used by or associated with such instructions. Non-limiting machine-readable medium examples may include solid-state memories, optical and magnetic media, or other tangible structures. Examples of machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

The instructions 755 (e.g., software, programs, an operating system (OS), etc.) or other data, stored on the mass storage device 751, can be accessed by the main memory 754 for use by the processor 750. The main memory 754 (e.g., DRAM) is typically fast, but volatile, and thus a different type of storage than the mass storage device 751 (e.g., an SSD), which is suitable for long-term storage, including while in an “off” condition. The instructions 755 or data in use by a user or the machine 700 are typically loaded in the main memory 754 for use by the processor 750. When the main memory 754 is full, virtual space from the mass storage device 751 can be allocated to supplement the main memory 754; however, because the mass storage device 751 is typically slower than the main memory 754, and write speeds are typically at least twice as slow as read speeds, use of virtual memory can greatly reduce user experience due to storage device latency (in contrast to the main memory 754, e.g., DRAM). Further, use of the mass storage device 751 for virtual memory can greatly reduce the usable lifespan of the mass storage device 751.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA-based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

The instructions 755 may further be transmitted or received over a communications network 759 using a transmission medium via the network interface device 753 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 757 may include one or more physical jacks (e.g., Ethernet, coaxial, or phone jacks) or one or more antennas to connect to the communications network 759. In an example, the network interface device 757 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by the machine 700, and includes instrumentalities to propagate digital or analog communications signals to facilitate communication of such instructions, which instructions may be implemented by software.

The following are example embodiments of devices and methods, in accordance with the teachings herein.

An example memory device 1 can comprise a pillar having a pillar fill with memory cells arranged in tiers along the pillar fill; a channel structure for the memory cells arranged along the pillar fill; and a liner structure along the pillar fill and disposed between and contacting the channel structure and the pillar fill, the liner structure being a vertical arrangement of multiple liners, with a liner of the multiple liners on and contacting the pillar fill having a material composition different from material composition of the pillar fill.

An example memory device 2 can include features of example memory device 1 and can include the multiple liners having material compositions and properties to provide the memory cells with a target threshold voltage.

An example memory device 3 can include features of any of the preceding example memory devices and can include the multiple liners to include a high-k dielectric liner.

An example memory device 4 can include features of any of the preceding example memory devices and can include the multiple liners having a high-k dielectric liner on and contacting the channel structure for the memory cells in a deck of the memory cells; and a second liner on and contacting the high-k dielectric liner such that the high-k dielectric is sandwiched between the channel structure and the second liner, the second liner being a nitride liner, a carbon liner, an oxide liner, or a liner of two or more of nitride, carbon, or oxide.

An example memory device 5 can include features of example memory device 4 and any of the preceding example memory devices and can include the high-k dielectric liner and the second liner having thicknesses based on a target threshold voltage.

An example memory device 6 can include features of example memory device 4 and any of the preceding example memory devices and can include the second liner having a non-uniform thickness.

An example memory device 7 can include features of example memory device 6 and any of the preceding example memory devices and can include the second liner having a linear graded thickness.

An example memory device 8 can include features of example memory device 4 and any of the preceding example memory devices and can include the high-k dielectric liner including an aluminum oxide, a hafnium oxide, or a zirconium oxide.

An example memory device 9 can include features of any of the preceding example memory devices and can include the pillar fill being a chemical vapor deposited oxide.

In an example memory device 10, any of the memory devices of example memory devices 1 to 9 may be incorporated into an electronic apparatus further comprising a host processor or memory controller and a communication bus extending between the host processor/memory controller and the memory device.

In an example memory device 11, any of the memory devices of example memory devices 1 to 10 may be modified to include any structure presented in another of example memory device 1 to 10.

In an example memory device 12, any apparatus associated with the memory devices of example memory devices 1 to 11 may further include a machine-readable storage device configured to store instructions as a physical state, wherein the instructions may be used to perform one or more operations of the apparatus.

In an example memory device 13, any of the memory devices of example memory devices 1 to 12 may be formed or operated in accordance with any of the below example methods 1 to 11.

An example memory device 14 can comprise a pillar having a pillar fill with memory cells arranged in tiers along the pillar fill; a channel structure for the memory cells arranged along the pillar fill; and a liner structure along the pillar fill and disposed between and contacting the channel structure and the pillar fill, the liner structure being a vertical arrangement including an oxide liner, a high-k liner, and a third liner, with a liner of the liner structure on and contacting the pillar fill having a material composition different from material composition of the pillar fill.

An example memory device 15 can include features of example memory device 1 and can include the third liner to include one or more of a nitride, a carbon, or an oxide.

An example memory device 16 can include features of any of the preceding example memory devices and can include the high-k liner being sandwiched between the oxide liner and the third liner.

An example memory device 17 can include features of any of the preceding example memory devices and can include the third liner being sandwiched between the oxide liner and the high-k liner.

In an example memory device 18, any of the memory devices of example memory devices 14 to 17 may be incorporated into an electronic apparatus further comprising a host processor or memory controller and a communication bus extending between the host processor/memory controller and the memory device.

In an example memory device 19, any of the memory devices of example memory devices 14 to 18 may be modified to include any structure presented in another of example memory device 14 to 18.

In an example memory device 20, any apparatus associated with the memory devices of example memory devices 14 to 19 may further include a machine-readable storage device configured to store instructions as a physical state, wherein the instructions may be used to perform one or more operations of the apparatus.

In an example memory device 21, any of the memory devices of example memory devices 14 to 20 may be formed or operated in accordance with any of the below example methods 1 to 11.

An example method 1 of forming a memory device can comprise forming a pillar having a pillar fill with memory cells arranged in tiers along the pillar fill; forming a channel structure for the memory cells arranged along the pillar fill; and forming a liner structure along the pillar fill and disposed between and contacting the channel structure and the pillar fill, including forming the liner structure as a vertical arrangement of multiple liners, with a liner of the multiple liners on and contacting the pillar fill having a material composition different from material composition of the pillar fill.

An example method 2 of forming a memory device can include features of example method 1 of forming a memory device and can include forming the liner structure to include: forming a high-k dielectric liner on and contacting the channel structure for the memory cells in a deck of the memory cells; and forming a second liner on and contacting the high-k dielectric liner such that the high-k dielectric liner is sandwiched between the channel structure and the second liner, the second liner being a nitride liner, a carbon liner, an oxide liner, or a liner of two or more of nitride, carbon, or oxide.

An example method 3 of forming a memory device can include features of example method 2 of forming a memory device and any of the preceding example methods of forming a memory device and can include forming the second liner having a thickness based on a target threshold voltage.

An example method 4 of forming a memory device can include features of example method 2 of forming a memory device and any of the preceding example methods of forming a memory device and can include forming the second liner having a varying thickness along a vertical direction of the pillar.

An example method 5 of forming a memory device can include features of any of the preceding example methods of forming a memory device and can include forming the liner structure to include forming a high-k liner sandwiched between an oxide liner and another liner, materials of the oxide liner and the other liner being different from material of the pillar fill.

An example method 6 of forming a memory device can include features of any of the preceding example methods of forming a memory device and can include forming the liner structure includes a third liner sandwiched between an oxide liner and a high-k liner.

An example method 7 of forming a memory device can include features of any of the preceding example methods of forming a memory device and can include forming the channel structure on a side of an opening in a stack for the tiers of memory cells; forming the liner structure on the channel structure vertically adjacent the tiers of memory cells, after forming the channel structure, including forming the multiple liners as two or more vertical liners adjacent each other; and forming the pillar fill, after forming the liner structure, such that the liner structure is sandwiched between the channel structure and the pillar fill and contacting the channel structure and the pillar fill.

In an example method 8, any of the example methods 1 to 7 of forming a memory device may be performed in forming an electronic apparatus further comprising a host processor and a communication bus extending between the host processor and a memory system.

In an example method 9 of forming a memory device, any of the example methods 1 to 8 of forming a memory device may be modified to include operations set forth in any other of example methods 1 to 8.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include performing functions associated with any features of example memory devices 1 to 21.

An example machine-readable storage device storing instructions, that when executed by one or more processors, cause a machine to perform operations, can comprise instructions to perform functions associated with any features of example memory devices 1 to 13 and example memory devices 14 to 21 or perform form methods associated with any features of example methods 1 to 11 of forming a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. The above description is intended to be illustrative, and not restrictive, and the phraseology or terminology employed herein is for the purpose of description. In addition, in the foregoing Detailed Description, it can be seen that various features are grouped together in a single embodiment for the purpose of streamlining the disclosure. Combinations of the above embodiments and other embodiments will be apparent to those of skill in the art upon studying the above description.

What is claimed is:

1. A memory device comprising:
a pillar having a pillar fill with memory cells arranged in tiers along the pillar fill;
a channel structure for the memory cells arranged along the pillar fill; and
a liner structure along the pillar fill and disposed between and contacting the channel structure and the pillar fill, the liner structure being a vertical arrangement of multiple liners, with a liner of the multiple liners on and contacting the pillar fill having a material composition different from material composition of the pillar fill.

2. The memory device of claim 1, wherein the multiple liners have material compositions and properties to provide the memory cells with a target threshold voltage.

3. The memory device of claim 1, wherein the multiple liners include a high-k dielectric liner.

4. The memory device of claim 1, wherein the multiple liners include:
a high-k dielectric liner on and contacting the channel structure for the memory cells in a deck of the memory cells; and
a second liner on and contacting the high-k dielectric liner such that the high-k dielectric liner is sandwiched between the channel structure and the second liner, the second liner being a nitride liner, a carbon liner, an oxide liner, or a liner of two or more of nitride, carbon, or oxide.

5. The memory device of claim 4, wherein the high-k dielectric liner and the second liner have thicknesses based on a target threshold voltage.

6. The memory device of claim 4, wherein the second liner has a non-uniform thickness.

7. The memory device of claim 6, wherein the second liner has a linear graded thickness.

8. The memory device of claim 4, wherein the high-k dielectric liner includes an aluminum oxide, a hafnium oxide, or a zirconium oxide.

9. The memory device of claim 1, wherein the pillar fill is a chemical vapor deposited oxide.

10. A memory device comprising:
a pillar having a pillar fill with memory cells arranged in tiers along the pillar fill;
a channel structure for the memory cells arranged along the pillar fill; and
a liner structure along the pillar fill and disposed between and contacting the channel structure and the pillar fill, the liner structure being a vertical arrangement including an oxide liner, a high-k liner, and a third liner, with a liner of the liner structure on and contacting the pillar fill having a material composition different from material composition of the pillar fill.

11. The memory device of claim 10, wherein the third liner includes one or more of a nitride, a carbon, or an oxide.

12. The memory device of claim 10, wherein the high-k liner is sandwiched between the oxide liner and the third liner.

13. The memory device of claim 10, wherein the third liner is sandwiched between the oxide liner and the high-k liner.

14. A method comprising:
forming a pillar having a pillar fill with memory cells arranged in tiers along the pillar fill;
forming a channel structure for the memory cells arranged along the pillar fill; and
forming a liner structure along the pillar fill and disposed between and contacting the channel structure and the pillar fill, including forming the liner structure as a vertical arrangement of multiple liners, with a liner of the multiple liners on and contacting the pillar fill having a material composition different from material composition of the pillar fill.

15. The method of claim 14, wherein forming the liner structure includes:
forming a high-k dielectric liner on and contacting the channel structure for the memory cells in a deck of the memory cells; and
forming a second liner on and contacting the high-k dielectric liner such that the high-k dielectric is sandwiched between the channel structure and the second liner, the second liner being a nitride liner, a carbon liner, an oxide liner, or a liner of two or more of nitride, carbon, or oxide.

16. The method of claim 15, wherein the method includes forming the second liner having a thickness based on a target threshold voltage.

17. The method of claim 15, wherein the method includes forming the second liner having a varying thickness along a vertical direction of the pillar.

18. The method of claim 14, wherein forming the liner structure includes forming a high-k liner sandwiched between an oxide liner and another liner, materials of the oxide liner and the other liner being different from material of the pillar fill.

19. The method of claim 14, wherein forming the liner structure includes a third liner sandwiched between an oxide liner and a high-k liner.

20. The method of claim 14, wherein the method includes
forming the channel structure on a side of an opening in a stack for the tiers of memory cells;
forming the liner structure on the channel structure vertically adjacent the tiers of memory cells, after forming the channel structure, including forming the multiple liners as two or more vertical liners adjacent each other; and
forming the pillar fill, after forming the liner structure, such that the liner structure is sandwiched between the channel structure and the pillar fill and contacting the channel structure and the pillar fill.
